(19) United States
(12) Patent Application Publication
(10) Pub. No.: US 2010/0288546 A1
(43) Pub. Date: Nov. 18, 2010

(54) Holding Member, Mounting Structure Having The Holding Member Mounted In Electric Circuit Board, and Electronic Part Having the Holding Member

(76) Inventor: Toshiaki Hayashi, Aichi (JP)

Correspondence Address: BARLEY SNYDER, LLC, 1000 WESTLAKES DRIVE, SUITE 275, BERWYN, PA, 19312, US

(21) Appl. No.: 12/845,363

(22) Filed: Jul. 28, 2010

Related U.S. Application Data
(63) Continuation of application No. PCT/JP2009/050841, filed on Jan. 21, 2009.

(30) Foreign Application Priority Data
Jan. 30, 2008 (JP) 2008-019277

(51) Int. Cl. H05K 1/18; H05K 1/00

(52) U.S. Cl. 174/260; 174/250

(57) ABSTRACT

A holding member includes a base section, a pair of leg sections, and inclined sections positioned along tip portions of the pair of leg sections. The base section is plate-like shape. The pair of leg sections extend in approximately equal directions to each other, and are configured to fit into a through hole of an electronic circuit board and contact an inner surface of the through hole. The inclined sections are positioned along respective tip portions of the pair of leg sections and extend in directions approaching each other and facing in opposite directions, while being inclined relative to a width direction of the base section. Furthermore, the inclined sections contact and press each other so that a tip of at least one of the pair of leg sections advances along the axis which is angled relative to the width direction of the base section when the pair of leg sections are pushed into the through hole and contact the inner surface of the through hole.

### CROSS-REFERENCE TO RELATED APPLICATIONS

This application is a continuation of PCT International Application No. PCT/JP2009/050841, filed Jan. 21, 2009, which claims priority under 35 U.S.C. §119 to Japanese Patent Application No. 2008-019277, filed Jan. 30, 2008.

### FIELD OF THE INVENTION

The invention relates to a holding member, and in particular, to a holding member for holding an electronic part on an electric circuit board, a mounting structure having such a holding member, and an electronic part having such a holding member.

### BACKGROUND

Conventionally, it is known to mount an electronic part such as a connector on an electric circuit board, by pushing a holding member attached to the electronic part into a through hole formed in the electric circuit board. Further, there is a case in which the holding member is soldered to the electric circuit board in order to firmly fix the electronic part to the electric circuit board.

As such a holding member, there is proposed, for example, a holding member having a pair of leg sections that extend in the approximately same direction from a tabular base section fixed to a connector. Each have respective wide-width spring pieces capable of being elastically displaced in a board thickness direction, and face each other. A second leg section is disposed between the pair of leg sections and extends in the same direction as the direction in which the pair of leg sections extend (see, for example, Japanese Patent Laid-Open No. 2007-128772). According to this holding member, molten solder streams along the second leg section thereby easily rising within the through hole in a solder flow process, and the strength of attachment of the connector to the electric circuit board after the soldering is high. When this holding member is pushed into the through hole, the pair of leg sections elastically deform in the board thickness direction. In a state in which the holding member is merely pushed into the through hole and yet to be soldered, the holding member is held not to fall off the electric circuit board by having the outer surfaces of the pair of leg sections being in contact with an inner surface of the through hole. Moreover, this holding member has such an advantage that the holding member does not damage the inner surface of the through hole when being inserted into (removed from) the through hole. However, this holding member has such a disadvantage that it is difficult to increase the elasticity (spring constant) of the leg sections. Therefore, this holding member has low holding strength in the state in which the holding member is merely pushed into the through hole and yet to be soldered. For this reason, for example, when the connector is grasped and handled by a robot while the holding member is in such a state, or when the holding member in such a state is pulled hard, the leg sections of the holding member may come out of the through hole.

### SUMMARY

In view of the foregoing circumstances, it is an object of the invention to provide a holding member that prevents a leg section from coming out of a through hole in a state of being merely pushed into through hole and yet to be soldered, without damaging a surface of an electric circuit board.

The holding member includes a base section, a pair of leg sections, and inclined sections positioned along tip portions of the pair of leg sections. The base section is plate-like shape. The pair of leg sections extend in approximately equal directions to each other, and are configured to fit into a through hole of an electronic circuit board and contact an inner surface of the through hole. The inclined sections are positioned along respective tip portions of the pair of leg sections and extend in directions approaching each other and facing in opposite directions, while being inclined relative to a width direction of the base section. Furthermore, the inclined sections contact and press each other so that a tip of at least one of the pair of leg sections slides along an axis which is angled relative to the width direction of the base section when the pair of leg sections are pushed into the through hole and contact the inner surface of the through hole.

### BRIEF DESCRIPTION OF THE DRAWINGS

The invention is described in more detail in the following with reference to the embodiments shown in the drawings. Similar or corresponding details in the Figures are provided with the same reference numerals. The invention will be described in detail with reference to the following figures of which:

FIG. 1 is an external perspective view of a holding member according to the invention;

FIG. 2 is a front view and a bottom view of the holding member according to the invention;

FIG. 3 is a front view and a bottom view of the holding member being is pushed into a through hole formed in an electric circuit board;

FIG. 4 is a front view and a bottom view of the holding member being further pushed into the through hole formed in the electric circuit board;

FIG. 5 is a front view and a bottom view of the holding member being further pushed through the through hole formed in the electric circuit board;

FIG. 6 is a cross-sectional view of a mounting structure in which the holding member is fixed to an electric circuit board by the solder in a solder flow process;

FIG. 7 is a perspective view of one embodiment of an electronic part having the holding member according to the invention;

FIG. 8 is a side view and a front view of the connector of FIG. 7 according to the invention; and

FIG. 9 is a perspective view of the electronic part of FIG. 7 having the holding member according to the invention.

### DETAILED DESCRIPTION OF THE EMBODIMENT(S)

Embodiments of the invention will be described below with reference to the drawings.

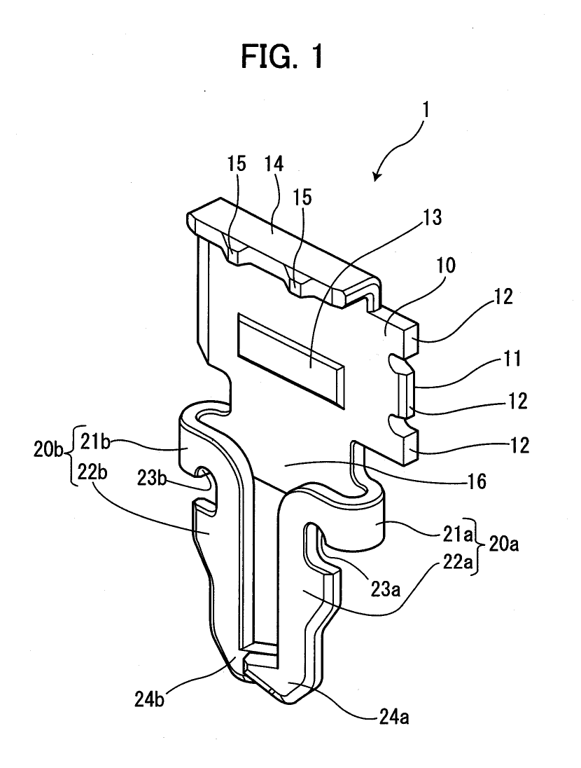

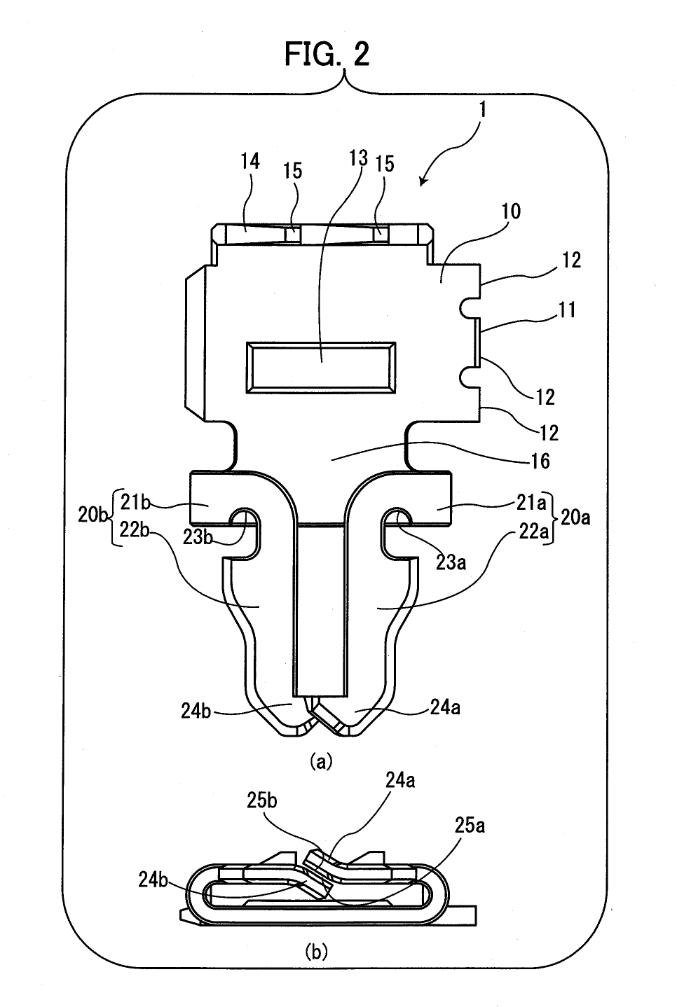

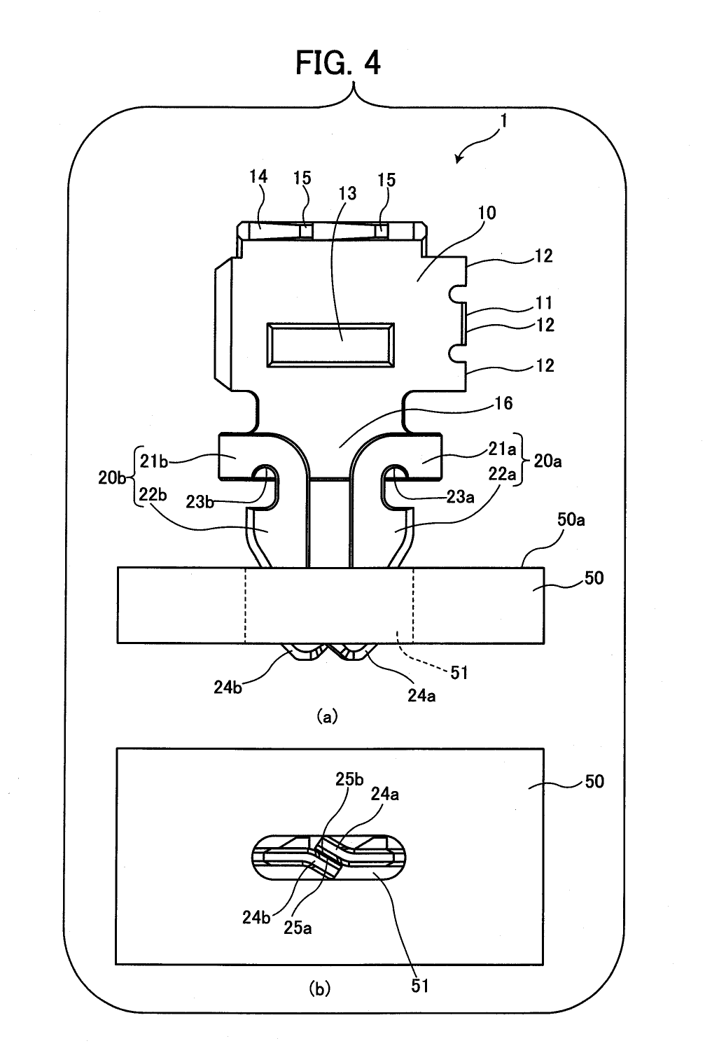

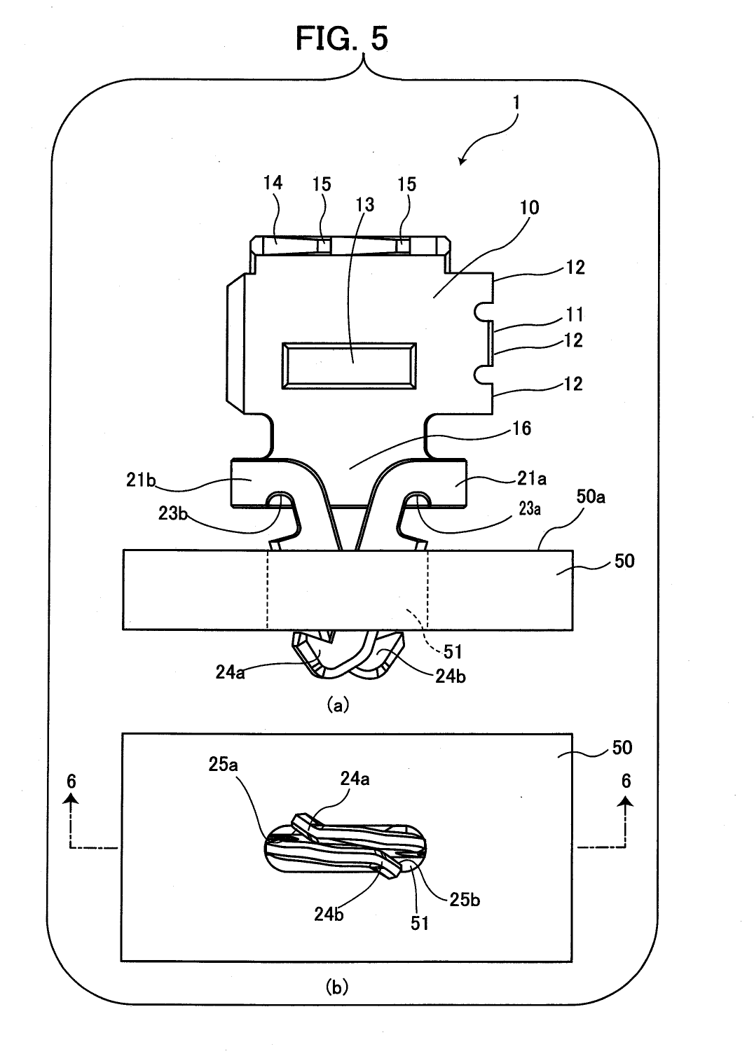

With reference to FIGS. 1-5, the electric circuit board 50 includes a through hole 51 and a part, which is near the through hole 51, of the electric circuit board 50. The through hole 51 is a slim (flat) aperture formed during manufacturing of the circuit board 50, and a copper plating layer (not illustrated) is formed on an inner surface 51a of the through hole 51. The thickness of the electric circuit board 50 is typically 1.2 to 1.6 mm. Incidentally, the through hole 51 is a long hole in the embodiment shown, but may be “a flat through hole” such as “an oval through hole”, “an ellipse through hole having a linear part” and “a rectangular through hole with rounded corners”, “an egg-shaped through hole” and “a rectangular through hole.”

The holding member 1 holds the electric circuit board 50 by being pushed, from a side where a mounting surface 50a is provided, into the through hole 51 formed in the electric circuit board 50. A board made of copper compound metal, such as brass is subjected to stamping, applying of pressure and bending, so that the holding member 1 is formed. Further, the holding member 1 is, for example, plated with tin, thereby having a solder receiving surface to be wet with molten solder. Incidentally, plating of the holding member 1 is not limited to the tin plating, and may be, for example, solder plating or gold plating. The holding member 1 includes a base section 10 and a pair of leg sections 20 (20a and 20b).

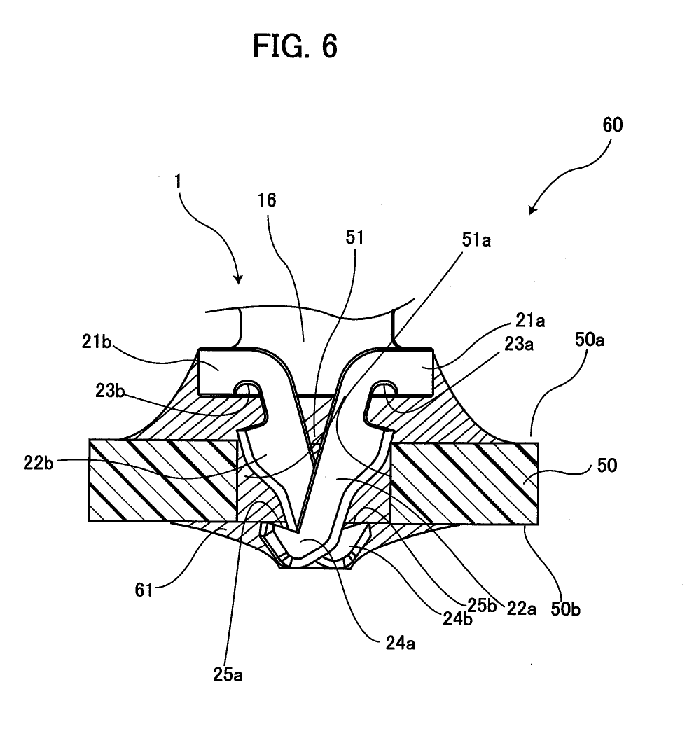

The base section 10 has a protruding section 16 that extends downward from one rectangular side. Projections 12 are positioned along a side edge 11 of the base section 10. The base section 10 is fixed by being press-fitted into a groove 83 formed on a flank of an insulating housing 82 of a connector 80 (see also FIG. 6). The projections 12 are provided to prevent removal. Further, projections 15 are formed on a bent section 14, which are positioned along an upper end of the base section 10. These projections 15 also are provided to prevent removal like the projections 12, and either the projections 12 or the projections 15 may be used depending on the way of attachment to the insulating housing 82 of the connector 80. Furthermore, a rib 13 for increasing resistance to bending moment is formed on the base section 10 by pressurizing processing. From the protruding section 16 included in the base section 10 and protruding downward from the one rectangular side, the pair of leg sections 20 (20a and 20b) extend in directions approximately equal to each other.

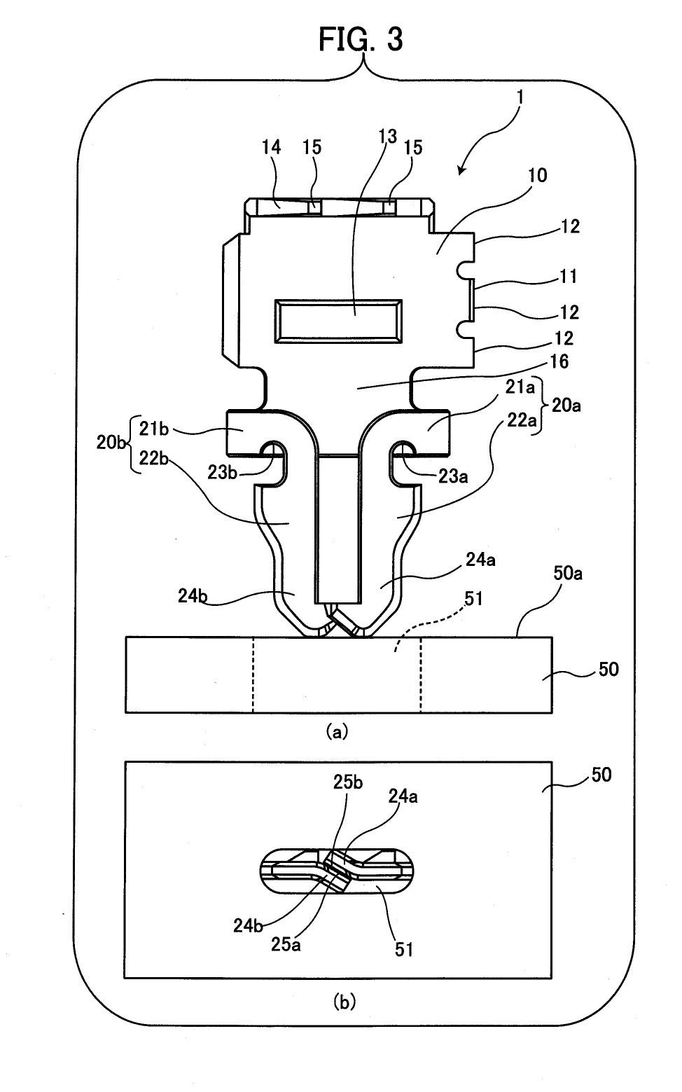

The pair of leg sections 20 are components to be pushed into the through hole 51 formed in the electric circuit board 50, while contacting the inner surface 51a of the through hole 51 at both ends in a longitudinal direction. The first leg section 20a, which is one of the pair of leg sections 20, is formed by bending a slim plate extending from one end of the protruding section 16. The first leg section 20a includes an intermediate section 21a extending from the protruding section 16 and an inserted section 22a extending from the intermediate section 21a continuously. The inserted section 22a is a part to be pushed into the through hole 51. The intermediate section 21a is bent to be shaped like a letter U and further extends in parallel with both the mounting surface 50a (see FIG. 3) of the electric circuit board 50 and the protruding section 16. The inserted section 22a is bent at the approximately right angle to the intermediate section 21a and extends downward. The inserted section 22a is approximately perpendicular to both the protruding section 16 and the mounting surface 50a (see FIG. 3). Further, provided between the intermediate section 21a and the inserted section 22a is a narrow-width section 23a formed to be narrow in width by being partially cut.

The second leg section 20b, which is the other of the pair of leg sections 20, extends from the other end of the protruding section 16 and is shaped so that the second leg section 20b and the first leg section 20a combined are symmetric. In other words, like the first leg section 20a, the second leg section 20b includes an intermediate section 21b and an inserted section 22b. Also, a narrow-width section 23b is provided between the intermediate section 21b and the inserted section 22b.

Of the pair of leg sections 20 (20a and 20b), the inserted sections 22a and 22b extend in directions approximately equal to each other. Further, formed at the respective tips of the pair of leg sections 20 (20a and 20b) are claws 24a and 24b having inclined sections 25a and 25b, respectively. These inclined sections 25a and 25b extend in directions approaching each other, yet face in opposite directions and are inclined relative to a width direction of the base section 10 to sit on each other. Therefore, when the pair of leg sections 20 are pushed into the through hole 51, and contact the inner surface 51a of the through hole 51 at both ends in the longitudinal direction, the inclined sections 25a and 25b contact and press each other. Additionally, the claws 24a and 24b formed at the respective tips of the pair of leg sections 20 advance along the inclined sections 25a and 25b, sliding along an axis which is angled relative to the width direction of the base section. Subsequently, the claws 24a and 24b pass through the through hole 51 and protrude beyond the through hole 51 in the board thickness direction of the base section 10, thereby being caught on an edge of the through hole 51.

The narrow-width sections 23a and 23b plastically deform in response to distortion produced when the inclined sections 25a and 25b contact and press each other while advancing along an axis which is angled relative to the width direction of the base section. As a result of plastic deformation, engagement of both of the claws 24a and 24b is secured.

In the shown embodiment, in the state in which the holding member 1 is merely pushed into the through hole 51 and yet to be soldered, the claws 24a and 24b formed at the respective tips of the pair of leg sections 20 are caught on the edge of the through hole 51, so that the holding member 1 is retained on the electric circuit board 50, thereby preventing the pair of leg sections 20 from coming out of the through hole 51, without damaging the surface of the electric circuit board 50.

Further, in the shown embodiment where the holding member 1 is merely pushed into the through hole 51 and yet to be soldered, the claws 24a and 24b formed at the respective tips of the pair of leg sections 20 are reliably caught on the edge of the through hole 51, as a result of plastic deformation of the narrow-width sections 23a and 23b. Each of the narrow-width sections 23a and 23b are formed to have a narrow width by being partially cut. Furthermore, in a process in which the inclined sections 25a and 25b advance along an axis which is angled relative to the width direction of the base section, while contacting and pressing each other and the pair of leg sections 20 are pushed in while contacting the inner surface 51a of the through hole 51 at both ends in the longitudinal direction, a force received by the inner surface 51a from the pair of leg sections 20 is small as compared to a case in which such narrow-width sections 23a and 23b are not provided, and thus, the inner surface 51a is not readily damaged.

Such a preferable feature is effective in, for example, a case in which the through hole 51 is formed near an edge portion of the electric circuit board 50 and a housing 82 also is close to the end portion so that only either one of the respective tips of the pair of leg sections 20 may be made to protrude in the board thickness direction of the base section 10 beyond the through hole 51. Further, according to such a preferable feature, thanks to the plastic deformation of the narrow-width section 23a formed to be narrow in width by being partially cut, in the state in which the pair of leg sections 20 are merely pushed into the through hole 51 and yet to be soldered, the tip of one of the pair of leg section is reliably caught on the edge of the through hole 51. Furthermore, when the inclined sections 25a advance slides along an axis which is angled relative to the width direction of the base section, while contacting and pressing each other and the pair of leg sections 20 are pushed into the through hole 51 while contacting the inner surface 51a of the through hole 51, a force received by the inner surface 51a from the pair of leg sections 20 is smaller than that in a case where such a narrow-width section 23a is not provided and thus, the inner surface 51a is not easily damaged.

The holding member 1 being inserted into the through hole 51 is soldered to the electric circuit board 50 together with terminals of the connector 80 in a solder flow process. According to the holding member 1 of the invention, the through hole 51 is almost filled with the pair of leg sections 20 being pushed in and therefore, molten solder 61 streams along the pair of leg sections 20 and easily rises within the through hole 51 in the solder flow process. Moreover, any void in the through hole 51 is filled with the solder 61 and thus, the strength of attachment after the soldering is higher than that of a conventional holding member 1.

Subsequently, a mounting structure 60 in which the holding member 1 is fixed to the electric circuit board 50 by the solder 61 will be described, together with a step in which the soldering is performed in the solder flow process.

FIG. 6 shows a mounting structure 60 in which the holding member 1 described above is fixed to the electric circuit board 50 by the solder 61.

Further, with reference to FIG. 6, the mounting structure 60 is shown, in which the holding member 1 is fixed to the electric circuit board 50 by the solder and at the same time depicts a state in which the molten solder adheres to the electric circuit board 50 and the holding member 1 in the solder flow process. Here, both the solder in a molten state in the solder flow process and the solder in a solid state are indicated by the same reference number 61 and will be described.

In the solder flow process, in a state in which the holding member 1 is pushed into the through hole 51, a soldered surface 50b of the electric circuit board 50 is dipped into molten solder 61. Then, both the copper plating layer (not illustrated) and the holding member 1 become wet with the molten solder 61. The copper plating layer is formed on an inner surface 51a of the through hole 51 and a part, which is near the through hole 51, of the mounting surface 50a. The molten solder flows along the surfaces of the pair of leg sections 20 (20a and 20b) and the inner surface 51a of the through hole 51, and rises within the through hole 51. As discussed, the through hole 51 is almost filled with the pair of leg sections 20 being pushed in. Therefore, the molten solder 61 is also drawn up. The molten solder 61 drawn up in the through hole 51 soon rises along the surfaces of the pair of leg sections 20 (20a and 20b).

As a result, as shown in FIG. 6, the molten solder 61 completely fills the through hole 51 and is further drawn up to go beyond the mounting surface 50a of the electric circuit board 50 from the through hole 51. Afterwards, on the mounting surface 50a of the electric circuit board 50, a fillet that spans the pair of leg sections 20 (20a and 20b) and the mounting surface 50a of the electric circuit board 50 is formed. The mounting structure 60 is formed when the molten solder 61 is cooled and solidified after the solder flow process. On the soldered surface 50b of the electric circuit board 50, a fillet that spans the pair of leg sections 20 (20a and 20b) and the soldered surface 50b is formed by the solder 61. Also, a fillet that spans the pair of leg sections 20 (20a and 20b) and the mounting surface 50a is formed on the mounting surface 50a. Incidentally, the mounting structure 60 illustrated in FIG. 6 is equivalent to an example of the mounting structure 60 of the invention.

According to the mounting structure 60 of the shown embodiment, the electric circuit board 50 and the pair of leg sections 20 (20a and 20b) of the holding member 1 are soldered to each other and thus, the holding member 1 is firmly fixed to the electric circuit board 50. In other words, the connector 80 having the holding member 1 is firmly fixed to the electric circuit board 50 by undergoing a soldering process.

The mounting structure 60 of the invention has the holding member 1 of the invention. Therefore, like this holding member 1, the mounting structure 60 has such an advantage that when the holding member 1 is soldered to and thereby mounted on the electric circuit board 50, in the state of being merely pushed into the through hole 51 and yet to be soldered, the holding member 1 is retained on the electric circuit board 50 by the tip of the leg section caught on the edge of the through hole 51, which prevents the pair of leg sections 20 from coming out of the through hole 51, without damaging the surface of the electric circuit board 50. Furthermore, when the holding member 1 is soldered to and thereby mounted on the electric circuit board 50, a wobble in the board thickness direction of the base section 10 is suppressed by the tip of the leg section caught on the edge of the through hole 51. Still furthermore, when the holding member 1 is soldered to and thereby mounted on the electric circuit board 50, since the pair of leg sections 20 are in contact with the inner surface 51a of the through hole 51, a wobble in the width direction of the base section 10 also is suppressed. Moreover, when the holding member 1 is soldered to and thereby mounted on the electric circuit board 50, the through hole 51 is almost filled with the pair of leg sections 20 being pushed in and thus, the molten solder 61 streams along the pair of leg sections 20 and easily rises within the through hole 51 in the solder flow process, and the electric circuit board 50 and the pair of leg sections 20 of the holding member 1 are soldered to each other over a wide area including the through hole 51. Therefore, the strength of attachment of the electronic part to the electric circuit board 50 is high.

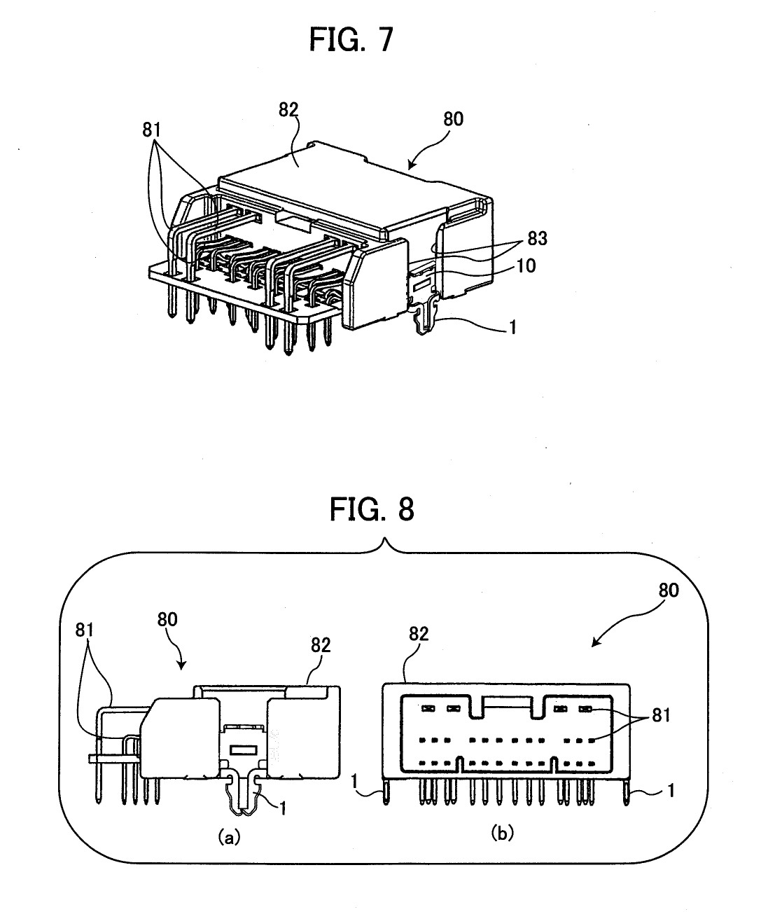

Subsequently, the connector 80 held on the electric circuit board 50 by the holding member 1 will be described, with reference to FIGS. 7-9.

FIG. 7 and FIG. 8 show a connector 80 that is an embodiment of the electronic part according to the invention. The connector 80 is mounted on the electric circuit board 50 built in an electronic device, and electrically connects a circuit on the electric circuit board 50 to another circuit by being mated with another connector 80 (not illustrated) paired with the connector 80.

The connector 80 includes the holding member 1 described above, contacts 81 to be connected with the circuit on the electric circuit board 50 and a housing 82 that secures the holding member 1 and the contacts 81. When the base section 10 of the holding member 1 is press-fitted into a groove 83 formed in the connector 80, the holding member 1 is attached to the connector 80.

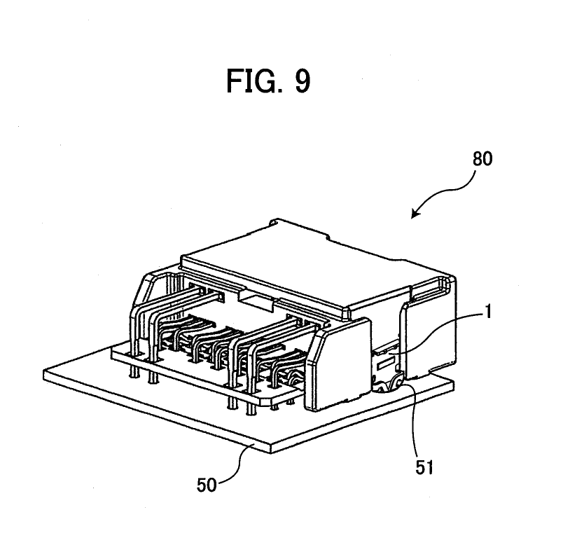

With reference to FIG. 9, the connector 80 is shown being held on the electric circuit board 50. When the holding member 1 is pushed into the through hole 51, the connector 80 is held on the electric circuit board 50. After the electric circuit board 50 in this state passes the solder flow process, the holding member 1 is soldered to the electric circuit board 50.

According to the connector 80 of the shown embodiment, in the state in which the holding member 1 is merely pushed into the through hole 51 and yet to be soldered, the claws 24a and 24b formed at the respective tips of the pair of leg sections 20 are caught on the edge of the through hole 51 so that the connector 80 is held on the electric circuit board 50, without damaging the surface of the electric circuit board 50. In other words, the pair of leg sections 20 are prevented from coming out of the through hole 51.

The electronic part of the invention has the holding member 1 of the invention. Therefore, like this holding member 1, the electronic part has such an advantage that in the state of being merely pushed into the through hole 51 and yet to be soldered, the electronic part is retained on the electric circuit board 50 by the tip of the leg section caught on the edge of the through hole 51, which prevents the pair of leg sections 20 from coming out of the through hole 51, without damaging the surface of the electric circuit board 50. Furthermore, a wobble in the board thickness direction of the base section 10 is suppressed by the tip of the leg section caught on the edge of the through hole 51. Still furthermore, since the pair of leg sections 20 are in contact with the inner surface 51a of the through hole 51, a wobble in the width direction of the base section 10 also is suppressed. Moreover, the through hole 51 is almost filled with the pair of leg sections 20 being pushed in and thus, the molten solder 61 streams along the pair of leg sections 20 and easily rises within the through hole 51 in the solder flow process. Therefore, the strength of attachment of the electronic part to the electric circuit board 50 after the soldering is high.

Incidentally, in the embodiment shown, the connector 80 has been described as an example of the electronic part according to the invention, but the invention is not limited to this example and is applied to other electronic parts held on an electric circuit board 50 by a holding member 1.

Further, as to the connector 80 of the embodiment shown, there has been described the example in which the holding member 1 is attached to the connector 80 and then soldered in the solder flow process. However, the invention is not limited to this example. For example, as illustrated in FIG. 6, the holding member 1 may be fixed to the connector 80 after the holding member 1 is soldered to the electric circuit board 50.

Furthermore, in the embodiment shown, there has been described the example in which the soldering is performed in the solder flow process, but the invention is not limited to this example. For example, the soldering may be performed in a solder reflow process by filling the through hole 51 with solder paste beforehand or in a soldering process using a soldering iron (so-called hand soldering).

Still further, in the embodiment shown, the holding member 1 has been described as being made of brass and plated with tin, but the invention is not limited to this example. The holding member 1 may be anything as long as the holding member 1 is made of metal and has a surface that becomes wet with molten solder 61. For example, when the holding member 1 is made of copper compound metal such as the brass like the holding member 1 of the embodiment shown, the tin plating may be omitted.

Moreover, in the embodiment shown, there has been described the example in which the pair of leg sections 20 are symmetric, and the respective tips of the pair of leg sections 20 protrude in the board thickness direction of the base section 10 beyond the through hole 51 and caught on the edge of the through hole 51 when the pair of leg sections 20 are pushed into the through hole 51. However, the pair of leg sections 20 of the invention are not limited to this example. When the pair of leg sections 20 are pushed into the through hole 51, the tip of only one of the pair of leg sections 20 may protrude in the board thickness direction of the base section 10 beyond the through hole 51 and be caught on the edge of the through hole 51.

Further, according to the holding member 1 of the invention, a wobble in the board thickness direction of the base section 10 is suppressed by the tip of the leg section caught on the through hole 51. Furthermore, since the pair of leg sections 20 are in contact with the inner surface 51a of the through hole 51, a wobble in the width direction of the base section 10 also is suppressed.

The foregoing illustrates some of the possibilities for practicing the invention. Many other embodiments are possible within the scope and spirit of the invention. It is, therefore, intended that the foregoing description be regarded as illustrative rather than limiting, and that the scope of the invention is given by the appended claims together with their full range of equivalents.

What is claimed is:

1. A holding member comprising:
a base section having a plate-like shape;
a pair of leg sections extending in approximately equal directions to each other, the pair of leg sections configured to fit into a through hole of an electronic circuit board and contact an inner surface of the through hole, and
inclined sections positioned along respective tip portions of the pair of leg sections and extending in directions approaching each other and facing in opposite directions while being inclined relative to a width direction of the base section;
wherein the inclined sections contact and press each other so that a tip of at least one of the pair of leg sections advances along an axis which is angled relative to the width direction of the base section when the pair of leg sections are pushed into the through hole and contact the inner surface of the through hole.

2. The holding member according to claim 1, wherein at least one tip portion is configured to catch an edge of the through hole when the at least one tip portion passes through the through hole and protrudes in a board thickness direction of the base section beyond the through hole.

3. The holding member according to claim 1, wherein the pair of leg sections are symmetric.

4. The holding member according to claim 3, wherein the pair of leg sections have narrow-width sections.

5. The holding member according to claim 4, wherein the narrow-width sections are narrow in width by being partially cut and plastically deform in response to distortion produced when the inclined sections advance along the axis while contacting and pressing each other.

6. The holding member according to claim 2, wherein one of the pair of leg sections includes a narrow-width section that is formed to be narrow in width by being partially cut and plastically deforms in response to distortion produced when the inclined sections advance in the axis while contacting and pressing each other.

7. The holding member according to claim 1, wherein the holding member is made of metal and has a solder receiving surface.

8. The holding member according to claim 4, wherein the holding member is made of metal and has a solder receiving surface.

9. The holding member according to claim 6, wherein the holding member is made of metal and has a solder receiving surface.

10. A mounting structure comprising:
an electric circuit board having a through hole;
a holding member having a pair of leg sections pushed into the through hole and holding an electronic part on the electric circuit board, the pair of leg sections configured to fit into a through hole of an electronic circuit board and contact an inner surface of the through hole; and
solder that fixes the holding member to the electric circuit board by filling the through hole into which the leg sections are being pushed.

11. The mounting structure according to claim 10, wherein the holding member further comprises a base section having a plate-like shape and inclined sections positioned along respective tip portions of the pair of leg sections and extending in directions approaching each other and facing in opposite directions while being inclined relative to a width direction of the base section.

12. The mounting structure according to claim 11, wherein the inclined sections contact and press each other so that a tip of at least one of the pair of leg sections advances along an axis which is angled relative to the width direction of the base section when the pair of leg sections are pushed into the through hole and contact the inner surface of the through hole.

13. The mounting structure according to claim 12, wherein at least one tip portion is configured to catch an edge of the through hole when the at least one tip portion passes through the through hole and protrudes in a board thickness direction of the base section beyond the through hole.

14. The mounting structure according to claim 12, wherein the pair of leg sections are symmetric.

15. The mounting structure according to claim 14, wherein the pair of leg sections have narrow-width sections.

16. The mounting structure according to claim 15, wherein the narrow-width sections are narrow in width by being partially cut and plastically deform in response to distortion produced when the inclined sections advances along the axis while contacting and pressing each other.

17. The mounting structure according to claim 16, wherein the holding member is made of metal and has a solder receiving surface.

18. The mounting structure according to claim 12, wherein one of the pair of leg sections includes a narrow-width section that is formed to be narrow in width by being partially cut and plastically deforms in response to distortion produced when the inclined sections advance along the axis while contacting and pressing each other.
